(19) United States
(12) Patent Application Publication
(10) Pub. No.: US 2025/0126780 A1
(43) Pub. Date: Apr. 17, 2025

(54) MEMORY DEVICE AND METHOD FOR MANUFACTURING THE SAME

(71) Applicant: Winbond Electronics Corp., Taichung City (TW)

(72) Inventors: Pin-Hung CHEN, Tainan City (TW); Jia-Wun WU, Kaohsiung City (TW)

(21) Appl. No.: 18/904,381

(22) Filed: Oct. 2, 2024

(30) Foreign Application Priority Data
Oct. 17, 2023 (TW) 112139570

(51) Int. Cl. H10B 12/00; H01L 21/768; H01L 29/423

(52) U.S. Cl. CPC H10B 12/488; H01L 21/76877; H10D 64/512

(57) ABSTRACT

A method for manufacturing a memory device is provided. The method includes providing a substrate, forming a dielectric layer on the substrate, and performing a patterning process to form a trench through the dielectric layer to the substrate. The method includes forming a first conductor layer at the bottom of the trench, conformally forming a first barrier layer in the trench, and performing a cleaning process to remove a portion of the first barrier layer on the sidewalls of the dielectric layer, and the first barrier layer is retained on the top surface of the first conductor layer. The method includes forming a second barrier layer over the first barrier layer, and forming a second conductor layer to fill the trench. The forming rate of the second barrier layer on the top surface of the first barrier layer is greater than on the sidewalls of the dielectric layer.

### CROSS REFERENCE TO RELATED APPLICATIONS

This application claims priority of Taiwan Patent Application No. 112139570 filed on Oct. 17, 2023, the entirety of which is incorporated by reference herein.

### BACKGROUND OF THE INVENTION

### Field of the Invention

The present disclosure relates to a semiconductor process technology, and in particular to a memory device and a method for manufacturing the same.

### Description of the Related Art

In order to maintain the performance of products at a lower cost, the process window in the current process for forming a memory device (e.g., dynamic random-access memory (DRAM) with buried word lines) is reduced as the dimension of the components continues to be scaled down. For example, when forming buried word lines, the metal or barrier layer may remain on the dielectric layer on the sidewalls of a trench in the buried word lines, which may unnecessarily affect the memory device and cause electrical problems such as reduced reliability and current leakage. Therefore, the industry still needs to improve the method of manufacturing memory devices to achieve the desired goal of maintaining the memory device yield.

### BRIEF SUMMARY OF THE INVENTION

An embodiment of the present disclosure provides a method for manufacturing a memory device. The method includes providing a substrate, forming a dielectric layer on the substrate, and performing a patterning process to form a trench through the dielectric layer to the substrate. The method includes forming a first conductor layer at the bottom of the trench and buried in the substrate, and conformally forming a first barrier layer in the trench and covering sidewalls of the dielectric layer and the top surface of the first conductor layer. The method further includes performing a cleaning process to remove a portion of the first barrier layer on the sidewalls of the dielectric layer, the first barrier layer is retained on the top surface of the first conductor layer, and forming a second barrier layer over the first barrier layer, and forming a second conductor layer to fill the trench. The forming rate of the second barrier layer on the top surface of the first barrier layer is greater than the forming rate of the second barrier layer on the sidewalls of the dielectric layer.

An embodiment of the present disclosure provides a memory device. The memory device includes a substrate and a buried word line buried in the substrate. The buried word line includes a first conductor layer. The buried word line includes a first barrier layer disposed on the top surface of the first conductor layer and a second barrier layer disposed on the top surface of the first barrier layer. The buried word line further includes a second conductor layer disposed on the second barrier layer. The second barrier layer contains chlorine in an elemental test.

### BRIEF DESCRIPTION OF THE DRAWINGS

In order to make the features and advantages of the present disclosure more obvious and easy to understand, different embodiments of the present disclosure, along with the figures, are described in detail as follows:

FIGS. 1-10 illustrate cross-sectional views at various intermediate stages of manufacturing the memory device, in accordance with the embodiments of the present disclosure.

### DETAILED DESCRIPTION OF THE INVENTION

Generally, in the process of forming the memory device, the process window is reduced as the dimension of the component continues to be scaled down. For example, when forming the buried word lines, the metal or barrier layer may be retained on the dielectric layer on the sidewalls of the trench of the buried word lines, which may unnecessarily affect the memory device and cause electrical problems (such as reduced reliability or current leakage). Although the residue may be avoided by adjusting the process seconds of the relevant film, a decrease in the thickness of the barrier layer may cause diffusion of the different conductor layers during subsequent high temperature processes, which may further affect the electrical properties of the memory device. The embodiment of the present disclosure utilizes the properties of the atomic layer deposition process to form the barrier layer with different thicknesses on different components, which effectively avoids the residual of the barrier layer on the dielectric layer on the sidewall of the trench. At the same time, the required thickness of the barrier layer may be maintained, thereby maintaining the yield of the memory device.

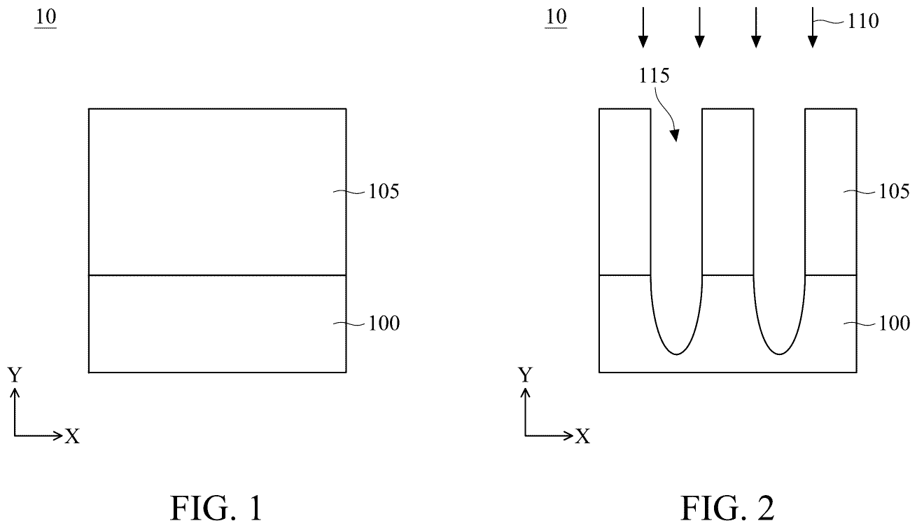

FIG. 1 illustrates a cross-sectional view of an intermediate stage of manufacturing the memory device 10, in accordance with the embodiments of the present disclosure. A substrate 100 is provided. In some embodiments, the substrate 100 may be an elemental semiconductor substrate, such as a silicon substrate, or a germanium substrate; a compound semiconductor substrate, such as silicon carbide (SiC), gallium arsenide (GaAs), indium arsenide (InAs), or indium phosphide (InP) substrate; or an alloy semiconductor substrate, such as SiGe, SiGeC, GaAsP, or GaInP. In other embodiments, the substrate 100 may be a semiconductor-on-insulator (SOI) substrate. The semiconductor-on-insulator substrate may include a base plate, a buried oxide layer disposed on the base plate, and a semiconductor layer disposed on the buried oxide layer.

Still referring to FIG. 1, a dielectric layer 105 is formed on the substrate 100. In other embodiments, the dielectric layer 105 may be a portion of the substrate 100, and the buried word line (e.g., the first conductor layer 120, the first barrier layer 125′, the second barrier layer 135, and the second conductor layer 150′) may be entirely formed in the substrate 100. In some embodiments, the dielectric layer 105 may be formed by a chemical vapor deposition (CVD) process. In some embodiments, the dielectric layer 105 may be formed from a dielectric material, such as silicon oxide, silicon nitride, silicon nitride, or a combination thereof.

FIG. 2 illustrates a cross-sectional view of the memory device 10 performing a patterning process 110, in accordance with the embodiments of the present disclosure. The patterning process 110 is performed to form a trench 115 through the dielectric layer 105 to the substrate 100. For example, a mask layer (not shown) is formed on the dielectric layer 105 first, and a photoresist pattern is formed on the mask layer by lithography and etching processes, followed by an etching process to transfer the photoresist pattern to the dielectric layer 105 and to the substrate 100 to form the trench 115. In some embodiments, the lithography process may include photoresist coating (e.g., spin-on coating), soft baking, mask alignment, exposure, post exposure baking (PEB), developing, rinsing, drying (e.g., hard baking), other suitable processes, or a combination thereof.

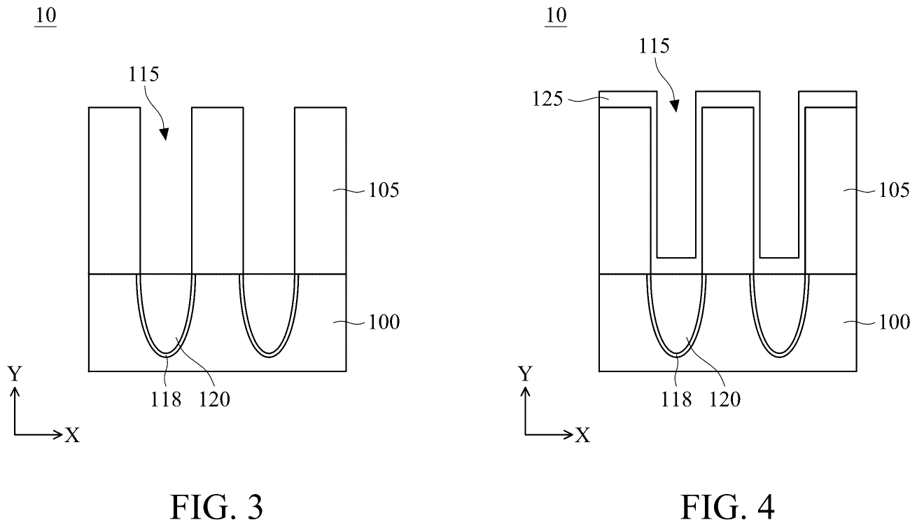

FIG. 3 illustrates a cross-sectional view of the memory device 10 forming the first conductor layer 120, in accordance with the embodiments of the present disclosure. After forming the trench 115, the first conductor layer 120 is formed at the bottom of the trench 115 and buried in the substrate 100. More specifically, forming the first conductor layer 120 includes forming a liner 118 in the trench 115, forming a first conductor material layer (not shown) on the liner 118, and performing an etching-back process on the first conductor material layer to form the first conductor layer 120. In some embodiments, the top surface of the first conductor layer 120 is level with the top surface of the substrate 100. In some embodiments, the liner 118 may be formed from titanium nitride (TiN), tungsten nitride (WN), tantalum nitride (TaN), or a combination thereof. In some embodiments, the liner 118 may be formed by using a chemical vapor deposition (CVD) process, a physical vapor deposition (PVD) process, an atomic layer deposition (ALD) process, or a combination thereof. In some embodiments, the first conductor layer 120 may be formed from a metallic material, such as tungsten (W), aluminum (Al), copper (Cu), cobalt (Co), ruthenium (Ru), other suitable metallic materials, or a combination thereof. In some embodiments, the first conductor layer 120 may be formed by using a physical vapor deposition (PVD) process, a chemical vapor deposition (CVD) process, an atomic layer deposition (ALD) process, or a combination thereof. In some embodiments, the etching-back process may include an anisotropic etching process (or a directional etching process), such as a reactive ion etching (RIE) process, plasma etching, inductively coupled plasma (ICP) etching, or dry etching of a combination thereof.

FIG. 4 illustrates a cross-sectional view of the memory device 10 forming the first barrier layer 125, in accordance with the embodiments of the present disclosure. The first barrier layer 125 is conformally formed in the trench 115 and covers the sidewalls of the dielectric layer 105 and the top surface of the first conductor layer 120. In some embodiments, the first barrier layer 125 may be formed from titanium nitride (TiN). In some embodiments, the first barrier layer 125 is formed by using a physical vapor deposition (PVD) process.

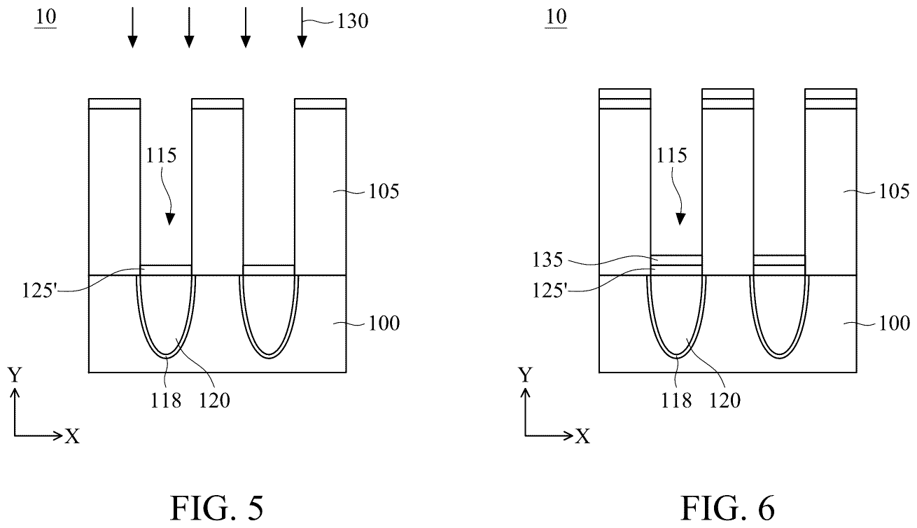

FIG. 5 illustrates a cross-sectional view of the memory device 10 performing a cleaning process 130, in accordance with the embodiments of the present disclosure. The cleaning process 130 is performed to remove a portion of the first barrier layer 125 located on the sidewalls of the dielectric layer 105, and the first barrier layer 125′ is retained on the top surface of the first conductor layer 120. The first barrier layer 125′ may serve as a film to avoid the diffusion between the first conductor layer 120 and the second conductor layer 150′ due to the subsequent high temperature process. In some embodiments, the cleaning process 130 includes a low-temperature sulfuric acid hydrogen peroxide mixture (SPM) cleaning process.

FIG. 6 illustrates a cross-sectional view of the memory device 10 forming a second barrier layer 135, in accordance with the embodiments of the present disclosure. The second barrier layer 135 is formed over the first conductor layer 120 and in contact with the first barrier layer 125′. In order to avoid the thickness of the barrier layer being too thin, in conventional processes, the barrier layer is usually chosen to be formed to a greater thickness, however, this may cause the barrier layer to be adversely retained on the sidewalls of the dielectric layer 105, causing a risk of current leakage from the subsequently formed conductor layer. In the embodiments of the present disclosure, by utilizing the properties of the atomic layer deposition (ALD) process, the formation of the barrier layer is divided into two stages, which not only reduces the possibility of the barrier layer being retained on the sidewalls of the dielectric layer 105, but also ensures that the barrier layer is formed to a desirable thickness. More specifically, for the atomic layer deposition process, the deposition rate is determined by the number of the cyclic depositions, i.e., there will be a lower deposition rate at the beginning of the process, and the deposition rate of the film may not be increased until the homogenization of the deposition surface. In the embodiments of the present disclosure, the properties that the dielectric layer 105 and the first barrier layer 125′ are surfaces of different materials are utilized. That is, the deposition of the second barrier layer 135 on the surface of the dielectric material may be considered to be at the early stage of the atomic layer deposition process, while the deposition of the second barrier layer 135 on the first barrier layer 125′ may be considered to be at the stage of the process after the deposition surface has been homogenized, thereby effectively controlling the formation of the second barrier layer 135. That is, the second barrier layer 135 is deposited on the first barrier layer 125′ in a manner similar to selective deposition. In other words, the forming rate of the second barrier layer 135 on the top surface of the first barrier layer 125′ is greater than the forming rate of the second barrier layer 135 on the sidewalls of the dielectric layer 105. In some embodiments, the thickness of the first barrier layer 125′ is greater than the thickness of the second barrier layer 135. In some embodiments, the ratio of the thickness of the first barrier layer 125′ to the thickness of the second barrier layer 135 is from about 3:1 to about 4:1. In some embodiments, the second barrier layer 135 solely covers the first barrier layer 125′ but not the sidewalls of the dielectric layer 105. In some embodiments, the area of the vertical projection of the first barrier layer 125′ on the substrate 100 is equal to the area of the vertical projection of the second barrier layer 135 on the substrate 100. In some embodiments, the thickness of the second barrier layer 135 is from about 1 nm to about 2 nm. In some embodiments, the sum of the thicknesses of the first barrier layer 125′ and the thicknesses of the second barrier layer 135 is less than about 6 nm. In some embodiments, the second barrier layer 135 may be formed from titanium nitride (TiN). In some embodiments, the second barrier layer 135 is formed by using an atomic layer deposition (ALD) process.

It should be noted that in the embodiments of the present disclosure, the first barrier layer 125′ is formed by using a physical vapor deposition (PVD) process. More specifically, the first barrier layer 125′ formed by the PVD process may contain only Ti and N as its constituent elements, and thus the first barrier layer 125′ is free of chlorine (Cl) in the elemental test. In the embodiments of the present disclosure, the second barrier layer 135 is formed by using an atomic layer deposition (ALD) process. More specifically, the second barrier layer 135 formed by the ALD process may contain Ti, N, Cl, and H as its constituent elements, and thus the second barrier layer 135 may contain chlorine in the elemental test. In some embodiments, the first barrier layer 125′ is disposed on the top surface of the first conductor layer 120, and the second barrier layer 135 is disposed on the top surface of the first barrier layer 125′.

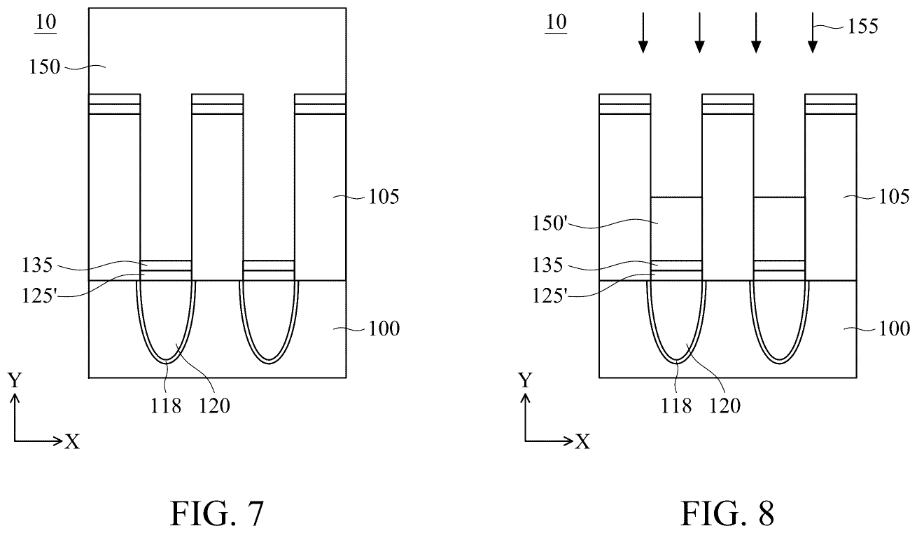

FIG. 7 illustrates a cross-sectional view of the memory device 10 forming a second conductor layer 150, in accordance with the embodiments of the present disclosure. FIG. 8 illustrates a cross-sectional view of the memory device 10 performing an etching-back process 155, in accordance with the embodiments of the present disclosure. The second conductor layer 150 is formed to fill the trench 115, in other words, the second conductor layer 150 is disposed on the second barrier layer 135. The second conductor layer 150 is separated from the first conductor layer 120 by the first barrier layer 125′ and the second barrier layer 135. The second barrier layer 135 is in direct contact with the bottom surface of the second conductor layer 150 and not in contact with the sidewalls of the second conductor layer 150. After forming the second conductor layer 150, an etching-back process 155 is performed on the second conductor layer 150 to form the second conductor layer 150′. After forming the second conductor layer 150′, the first conductor layer 120, the first barrier layer 125′, the second barrier layer 135, and the second conductor layer 150′ may be regarded as a buried word line of the memory device 10. In some embodiments, the material of the second conductor layer 150 may include polycrystalline silicon. In some embodiments, the etching-back process 155 may include an anisotropic etching process (or a directional etching process), such as a reactive ion etching (RIE) process, plasma etching, inductively coupled plasma (ICP) etching, or dry etching of a combination thereof.

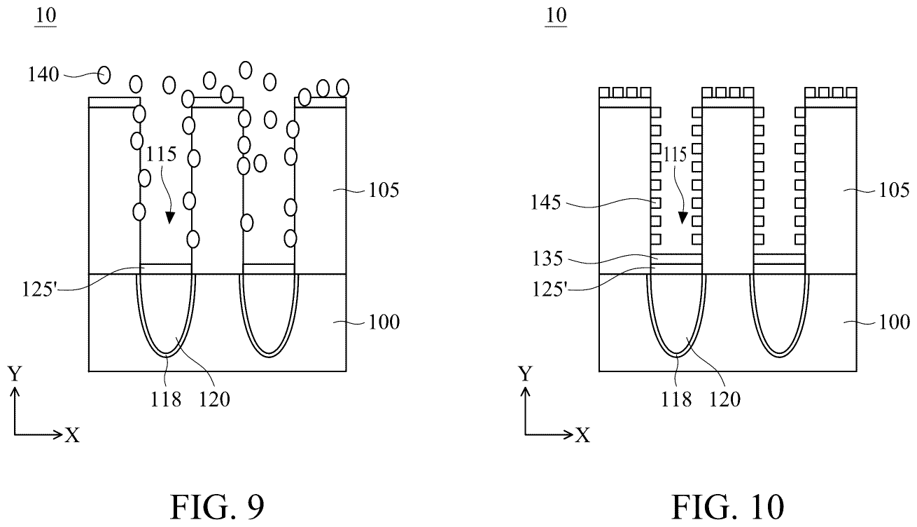

FIG. 9 illustrates a cross-sectional view of the memory device 10 performing a plasma cleaning process 140, in accordance with the embodiments of the present disclosure. FIG. 10 illustrates a cross-sectional view of the memory device 10 forming a second barrier layer 135, in accordance with the embodiments of the present disclosure. In addition to the properties by using the atomic layer deposition process, in some embodiments, after performing the cleaning process 130 and before forming the second barrier layer 135, a plasma cleaning process 140 may be performed to retain radicals 145 on the sidewalls of the dielectric layer 105. The radicals 145 may be used to reduce the forming rate of the second barrier layer 135 on the sidewalls of the dielectric layer 105. After performing the plasma cleaning process 140, similar to FIG. 6, the second barrier layer 135 is formed over the first conductor layer 120 and in contact with the first barrier layer 125′. The utilization of the radicals 145 further reduces the atomic layer deposition process to produce surface homogenization on the surface of the dielectric layer 105 and inhibits the formation of the second barrier layer 135.

After forming the buried word lines (including such as the first conductor layer 120, the first barrier layer 125′, the second barrier layer 135, and the second conductor layer 150′), other semiconductor processes may be performed continuously to form the various features and components of the memory device 10, which will not be described herein.

In summary, by dividing the formation of the barrier layer into two stages, the embodiment of the present disclosure utilizes the properties of the atomic layer deposition process to effectively control the thickness of the barrier layer. At the same time, the formation and retention of the barrier layer on the sidewalls of the dielectric layer is avoided, further maintaining the yield of the memory device.

The scope of the present disclosure is not limited to the technical solutions consisting of specific combinations of the technical features described above, but should also cover other technical solutions consisting of any combinations of the technical features described above or their equivalent features, all of which are within the scope of the protection of the present disclosure.

What is claimed is:

1. A method for manufacturing a memory device, comprising:
providing a substrate;
forming a dielectric layer on the substrate;
performing a patterning process to form a trench through the dielectric layer to the substrate;
forming a first conductor layer at a bottom of the trench and buried in the substrate;
conformally forming a first barrier layer in the trench and covering sidewalls of the dielectric layer and a top surface of the first conductor layer;
performing a cleaning process to remove a portion of the first barrier layer on the sidewalls of the dielectric layer, and the first barrier layer is retained on the top surface of the first conductor layer;
forming a second barrier layer over the first barrier layer; and
forming a second conductor layer to fill the trench,
wherein a forming rate of the second barrier layer on a top surface of the first barrier layer is greater than a forming rate of the second barrier layer on the sidewalls of the dielectric layer.

2. The method as claimed in claim 1, wherein the second barrier layer solely covers the first barrier layer and does not cover the sidewalls of the dielectric layer.

3. The method as claimed in claim 1, wherein the second conductor layer is separated from the first conductor layer by the first barrier layer and the second barrier layer.

4. The method as claimed in claim 1, wherein after performing the cleaning process and before forming the second barrier layer, the method further comprising:
performing a plasma cleaning process to retain a radical on the sidewalls of the dielectric layer, wherein the radical reduces the forming rate of the second barrier layer.

5. The method as claimed in claim 1, wherein the first barrier layer is formed by a physical vapor deposition process.

6. The method as claimed in claim 1, wherein the second barrier layer is formed by an atomic layer deposition process.

7. The method as claimed in claim 1, wherein the cleaning process comprises a low-temperature sulfuric acid hydrogen peroxide mixture (SPM) cleaning process.

8. The method as claimed in claim 1, wherein a thickness of the first barrier layer is greater than a thickness of the second barrier layer.

9. The method as claimed in claim 8, wherein a ratio of the thickness of the first barrier layer to the thickness of the second barrier layer is from about 3:1 to about 4:1.

10. The method as claimed in claim 1, wherein the top surface of the first conductor layer is level with a top surface of the substrate.

11. A memory device, comprising:
a substrate; and
a buried word line buried in the substrate, wherein the buried word line comprises:
a first conductor layer;
a first barrier layer disposed on a top surface of the first conductor layer;
a second barrier layer disposed on a top surface of the first barrier layer; and
a second conductor layer disposed on the second barrier layer,
wherein the second barrier layer contains chlorine in an elemental test.

12. The memory device as claimed in claim 11, wherein the first barrier layer is free of chlorine in the elemental test.

13. The memory device as claimed in claim 11, wherein a sum of a thickness of the first barrier layer and a thickness of the second barrier layer is less than about 6 nm.

14. The memory device as claimed in claim 11, wherein a thickness of the first barrier layer is greater than a thickness of the second barrier layer.

15. The memory device as claimed in claim 14, wherein a ratio of the thickness of the first barrier layer to the thickness of the second barrier layer is from about 3:1 to about 4:1.

16. The memory device as claimed in claim 11, wherein the second barrier layer is in direct contact with a bottom surface of the second conductor layer and not with sidewalls of the second conductor layer.

17. The memory device as claimed in claim 11, wherein a top surface of the first conductor layer is level with a top surface of the substrate.

18. The memory device as claimed in claim 11, wherein the second conductor layer is separated from the first conductor layer by the first barrier layer and the second barrier layer.

19. The memory device as claimed in claim 11, wherein a thickness of the second barrier layer is from about 1 nm to about 2 nm.

20. The memory device as claimed in claim 11, wherein an area of a vertical projection of the first barrier layer on the substrate is equal to an area of a vertical projection of the second barrier layer on the substrate.
